(19) United States
(12) Patent Application Publication
(10) Pub. No.: US 2016/0248049 A1
(43) Pub. Date: Aug. 25, 2016

(54) DEPOSITION APPARATUS

(71) Applicant: Samsung Display Co., Ltd., Yongin-si (KR)

(72) Inventors: Jae Min HONG, Cheonan-si (KR); Jung-Hoon KIM, Pohang-si (KR); Hong Ryul KIM, Seoul (KR); Suk Beom YOU, Anyang-si (KR); Sang Min YI, Suwon-si (KR); Young-Geun CHO, Seoul (KR)

(21) Appl. No.: 14/874,241

(22) Filed: Oct. 2, 2015

(30) Foreign Application Priority Data
Feb. 25, 2015 (KR) 10-2015-0026805

(51) Int. Cl. H01L 51/56; C23C 14/35; H01L 51/00

(52) U.S. Cl. CPC H01L 51/56; H01L 51/0011; H01L 51/001; C23C 14/35; H01L 2251/566

(57) ABSTRACT

A deposition apparatus comprises a chamber, a deposition material supplier positioned in the chamber and configured to contain and supply a deposition material, a substrate holder disposed in the chamber and configured to hold a substrate such that a major surface of the substrate faces the deposition material supplier; and a mask retainer disposed in the chamber and configured to retain a mask disposed over the major surface of the substrate. The mask retainer comprises a base, and a plurality of magnets coupled to the base, at least one of the plurality of magnets being movable with respect to the base, the plurality of magnets being configured to apply magnetic force to the mask such that the mask is fixed to the substrate without substantial movement of the mask with respect to the substrate during deposition of the deposition material.

### CROSS-REFERENCE TO RELATED APPLICATION

This application claims priority to and the benefit of Korean Patent Application No. 10-2015-0026805 filed in the Korean Intellectual Property Office on Feb. 25, 2015, the entire contents of which are incorporated herein by reference.

### BACKGROUND

(a) Field

The present disclosure relates to a deposition apparatus.

(b) Discussion of the Related Technology

Flat display technologies are applied to large electronic products in addition to small electronic products. Display devices convert electric signals representing information to images so that people can visually recognize the information. As the display device, various apparatuses such as an organic light emitting device, a liquid crystal display, and a plasma display device have been mainly used.

The above information disclosed in this Background section is only for enhancement of understanding of the background of the invention and therefore it may contain information that does not form the prior art that is already known in this country to a person of ordinary skill in the art.

### SUMMARY

Aspects of the present invention provide a deposition apparatus capable of improving cohesion between a substrate and a mask by uniformly providing a magnetic force to the mask.

One aspect of the invention provides a deposition apparatus, which may comprise: a chamber; a deposition material supplier positioned in the chamber and configured to contain and supply a deposition material; a substrate holder disposed in the chamber and configured to hold a substrate such that a major surface of the substrate faces the deposition material supplier; and a mask retainer disposed in the chamber and configured to retain a mask disposed over the major surface of the substrate, wherein the mask retainer comprises: a base, and a plurality of magnets coupled to the base, at least one of the plurality of magnets being movable with respect to the base, the plurality of magnets being configured to apply magnetic force to the mask such that the mask is fixed to the substrate without substantial movement of the mask with respect to the substrate during deposition of the deposition material.

In the foregoing apparatus, the mask comprises an active region comprising a plurality of openings through which the deposition material passes and an inactive region which corresponds to a region other than the deposition region of the substrate, and wherein the plurality of magnets are disposed to overlap the inactive region. The at least one of the plurality of magnets may be configured to move relative to the substrate and the mask such that the plurality of magnets are disposed to overlap the inactive region when viewed in a direction perpendicular to the major surface. The plurality of magnets may be configured to move along a first direction parallel with the major surface of the substrate. The plurality of magnets may be configured to move along a second direction vertical to the major surface of the substrate.

Still in the foregoing apparatus, each of the plurality of magnets may be coupled with the base by a position adjustment gear. Each of the plurality of magnets may be coupled with the base by a micro actuator. The plurality of magnets may comprise a first magnet and a second magnet immediately neighboring the first magnet, each of the first and second magnets having N and S magnetic poles, wherein the first and second magnets are arranged such that N magnetic pole of the first magnet and S pole of the second magnet are positioned adjacent the mask.

Further in the foregoing apparatus, the deposition material supplier may be configured to evaporate the deposition material such that the evaporated deposition material moves toward the substrate and is deposited over the major surface. The substrate holder may be configured to hold the substrate to be disposed between the mask and the plurality of magnets. The plurality of magnets do not contact the mask. The retainer does not contact the mask.

Another aspect of the invention provides a method of making at least one organic light emitting display device, which may comprise: providing the foregoing apparatus; placing a substrate comprising a major surface over which the deposition material is to be deposited such that the major surface faces the deposition material supplier; placing a mask comprising an active region which comprises a plurality of openings through which a deposition material passes and an inactive region next to the active region, wherein the substrate is disposed between the mask and the plurality of magnets; and supplying a deposition material contained in the deposition material supplier toward the substrate through the plurality of openings to deposit the deposition material over the major surface while the mask is fixed to the substrate without substantial movement of the mask with respect to the substrate by magnetic force applied to the mask by the plurality of magnets, thereby making an organic light emitting display device.

In the foregoing method, the method may further comprise moving at least one of the plurality of magnets subsequently to placing the mask or prior to placing the mask such that the plurality of magnets overlap the inactive region when viewed in a direction perpendicular to the major surface while the mask is fixed to the substrate for deposition. None of the plurality of magnets may overlap the active region when viewed in the direction. Supplying may comprise evaporating the deposition material in the deposition material supplier, wherein the evaporated deposition material is transferred through the openings and deposited over the major surface.

Still in the foregoing method, the mask may comprise an additional active region comprising a plurality of openings through which the deposition material passes, wherein the inactive region is disposed between the active region and the additional active region. The deposition material may be supplied through the openings of the additional active region, thereby forming an additional organic light emitting display device. The method may further comprise cutting the substrate to divide the organic light emitting display device and the additional organic light emitting display device. The deposition material may comprise at least one selected from the group consisting of an organic light emitting material, a metal, a metal oxide electrode material and a color filter material.

An embodiment of the present invention provides a deposition apparatus, including: a chamber having an inside formed with vacuum atmosphere; a deposition material accommodating part positioned in the chamber and having a deposition material accommodated and vaporized therein; a substrate fixing part disposed to be opposite to the deposition material accommodating part and having a substrate fixed thereto; and a mask fixing part disposed on one surface of the substrate and fixing a mask to the other surface of the substrate using a magnetic force, in which the mask fixing part includes: a plurality of magnets providing a magnetic force to the mask; and a plate with which the plurality of magnets are movably coupled.

The mask may include an active region having openings through which the deposition material passes and corresponding to a shape of a deposition region of the substrate and an inactive region which corresponds to a region other than the deposition region of the substrate and the plurality of magnets may be movably disposed to have higher magnetic force strength in the inactive region than in the active region.

The plurality of magnets may move along a first direction parallel with the plate and in this case, the plurality of magnets may move along a second direction vertical to the plate.

The plurality of magnets may be each coupled with the plate by a position adjustment gear or the plurality of magnets may be each coupled with the plate by a micro actuator.

The plurality of magnets may each have a disposition of magnetic poles which is opposite to that of magnetic poles of adjacent magnets.

According to an embodiment of the present invention, it is possible to more firmly attach the mask to the substrate during the performance of the deposition process within the deposition apparatus to reduce the defect occurrence rate of products.

### BRIEF DESCRIPTION OF THE DRAWINGS

FIG. 1 is a diagram illustrating a deposition apparatus according to an embodiment of the present invention.

FIG. 2 is a diagram illustrating an appearance before magnets move, according to an embodiment of the present invention.

FIG. 3 is a diagram illustrating an appearance after the magnets of FIG. 2 move.

FIGS. 4 to 7 are diagrams illustrating a disposition relationship of a plate and magnets, according to a modified example of the present invention

FIG. 8 is a diagram illustrating a disposition of the magnets moving in a first direction and a second direction, according to an embodiment of the present invention.

### DETAILED DESCRIPTION OF THE EMBODIMENTS

Hereinafter, embodiments of the present invention will be described in detail with reference to the drawings. However, in describing embodiments of the present invention, the description of well-known functions or constructions will be omitted to make a gist of the present invention clear.

Generally, a deposition process which vaporizes materials such as metal to form a thin film has been used to manufacture these display devices. The deposition process may be mainly used to form a thin film transistor, form a circuit, or form a component such as an emission layer of the display device.

To perform a process of depositing the thin film, a mask having openings at a region in which the thin film will be formed is disposed on a substrate and then materials to be deposited on the substrate are vaporized under the vacuum atmosphere.

In this case, when the mask moves or is not firmly fixed, the material may be deposited to the region in which the deposition region should not be formed. In this case, a circuit may be formed up to a region in which the circuit should not be formed or product defects such as misalignment due to an error of the deposition region may occur in processes to be performed later.

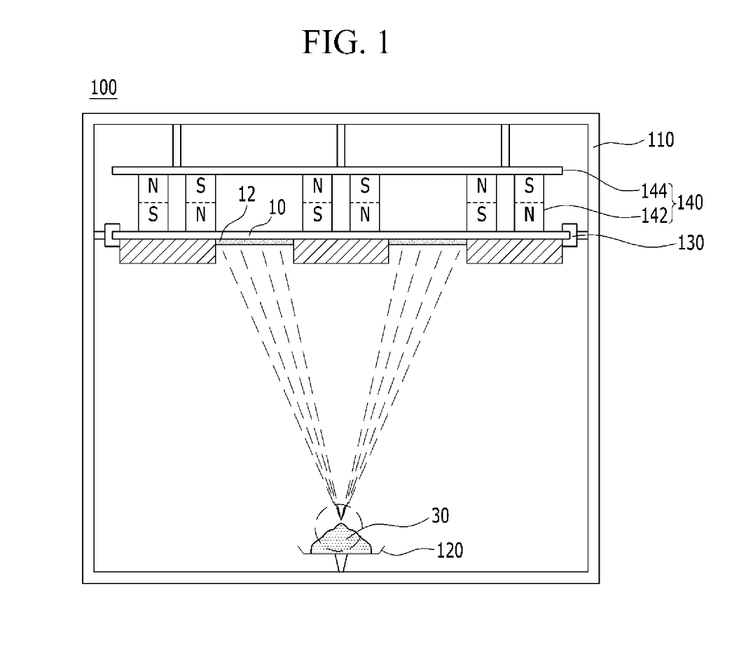

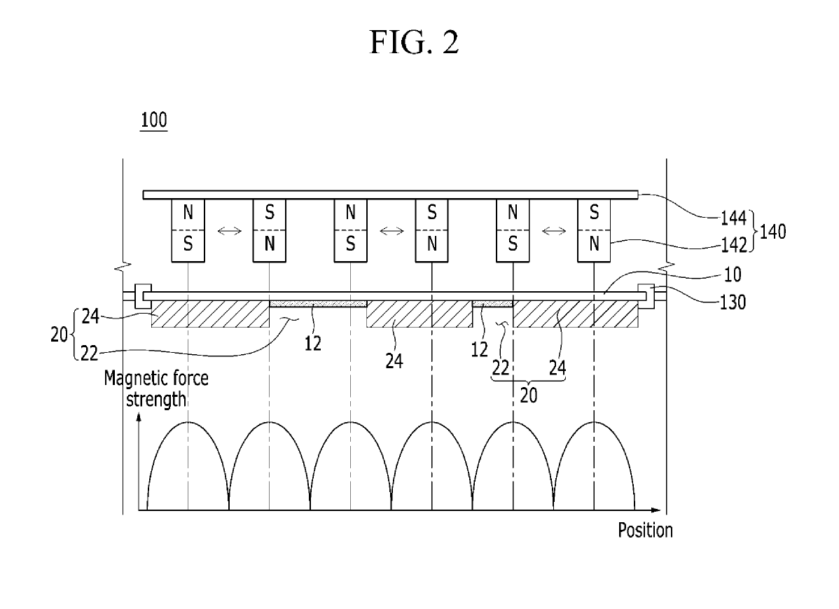

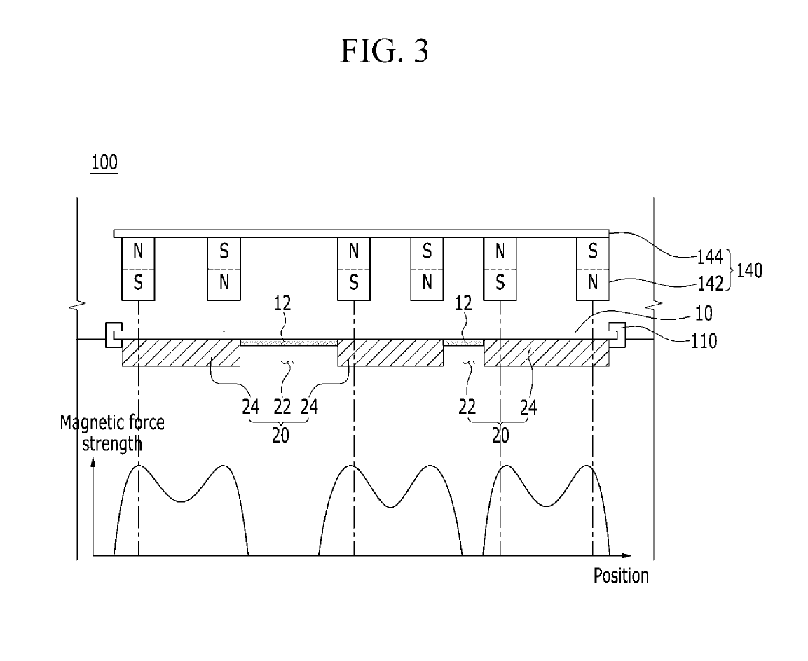

FIG. 1 is a diagram illustrating a deposition apparatus according to an embodiment of the present invention, FIG. 2 is a diagram illustrating an appearance before magnets move, according to an embodiment of the present invention, and FIG. 3 is a diagram illustrating an appearance after the magnets of FIG. 2 move.

As illustrated in FIGS. 1 to 3, a deposition apparatus 100 according to an embodiment of the present invention includes a chamber 100, a deposition material accommodating part or deposition material supplier 120, a substrate fixing part or substrate holder 130, and a mask fixing part or mask retainer 140.

The chamber 10 has an inside formed with vacuum atmosphere while a deposition material 30 is deposited and includes a housing which may be blocked from the outside.

Herein, the “vacuum atmosphere” does not mean only the state in which no material is present in the chamber but may mean a state approaching vacuum and may mean the state in which inert gas is injected into the chamber to reduce a pressure difference from the outside. Any deposition environment from which the occurrence possibility of other chemical reactions other than the deposition process while the deposition material 30 is deposited may be excluded may be included in the “vacuum atmosphere” according to embodiments of the present invention.

The deposition material accommodating part 120 is disposed within the chamber 110 and is a part in which the deposition material 30 is accommodated and vaporized. The deposition material accommodating part 120 according to the embodiment of the present invention may be made of a ceramic material having strong resistance against heat and chemical reaction like a furnace but is not limited thereto, and therefore any accommodating part made of a material which may accommodate the deposition material 30 without reacting to the deposition material 30 even at high temperature may be included in the scope of the present invention.

The deposition material 30 may be metal, but metal oxide such as indium tin oxide (ITO) is used recently. In addition, any kind of materials which need to be formed as the thin film on the substrate 10 may be used, and therefore the scope of the present invention is not limited by a kind of deposition material 30.

As illustrated in FIG. 1, the substrate fixing part 130 is disposed at a position opposite to the deposition material accommodating part 120 within the chamber 110 and thus the deposition material 30 vaporized from the deposition material accommodating part 120 may be smoothly attached. The substrate fixing part or substrate holder 130 is formed as, for example, a jig to fix the substrate 10 while the deposition process is performed.

The embodiment of the present invention illustrates that the substrate fixing part 130 is formed in a jig form as illustrated in FIG. 1, but is not limited thereto, and the substrate fixing part 130 according to various embodiments of the present invention which disposes the substrate 10 over the plate 144, fixes the substrate 10 by an intake scheme using an intake apparatus, or the like may be provided.

The substrate 10 fixed to the substrate fixing part 130 according to the embodiment of the present invention may be made of materials such as glass and plastic but may be made of a rigid material or a flexible material.

The mask fixing part 140 is disposed on one surface of the substrate 10 and includes a plurality of magnets 142 and the plate 144. The mask 20 is disposed on the other surface of the substrate 10 and the mask 20 according to the embodiment of the present invention may be made of a material which may be fixed by a magnetic force generated from the magnet 142 of the mask fixing part. Therefore, the mask 20 according to the embodiment of the present invention may mainly be a metal material, but any material which may be fixed by the magnetic force in addition to metal may be used as the mask 20 according to the embodiment of the present invention.

As described above, to fix the mask 20, the mask fixing part 140 according to the embodiment of the present invention includes the plurality of magnets 142. Further, the plurality of magnets 142 is movably coupled with the plate 144.

The plurality of magnets 142 according to the embodiment of the present invention moves to change magnetic force strength at each position. Describing in detail, the plurality of magnets 142 according to the embodiment of the present invention may be movably disposed to have higher magnetic force strength in an inactive region 24 than in an active region 22 of the mask 20. In embodiments, the magnet may be a permanent magnet or an electric magnet.

The mask 20 according to the embodiment of the present invention includes the active region 22 and the inactive region 24. The active region 22 has a plurality of openings and corresponding to the deposition region 12 formed by deposition of the deposition material 30 on the substrate 10 to have the deposition material 30 passing therethrough and the inactive region 24 is a region through which the deposition material 30 does not pass as a region which corresponds to a region other than the deposition region 12 of the substrate 10.

In this case, as illustrated in FIG. 2, even though the plurality of magnets 142 has the high magnetic force strength in the opened active region 22, the magnets may not firmly fix the mask 20. When the mask 20 is not firmly fixed while the deposition process is performed, the deposition material 30 may be deposited up to the region other than the deposition region 12, and thus it is highly likely to cause defects in completed products.

Therefore, as illustrated in FIG. 3, the plurality of magnets 142 according to the embodiment of the present invention may move to have high magnetic force strength in the inactive region 24 of the mask 20 which may block the deposition material 30.

According to the embodiment of the present invention, the plurality of magnets 142 each are coupled with the plate 144 by a position adjustment gear 146 and thus a user may move a position as he/she wishes. Meanwhile, according to another embodiment of the present invention, the plurality of magnets 142 each may be coupled with the plate 144 by a micro actuator 148. As a result, each position of the plurality of magnets 142 may separately move by an electronic control.

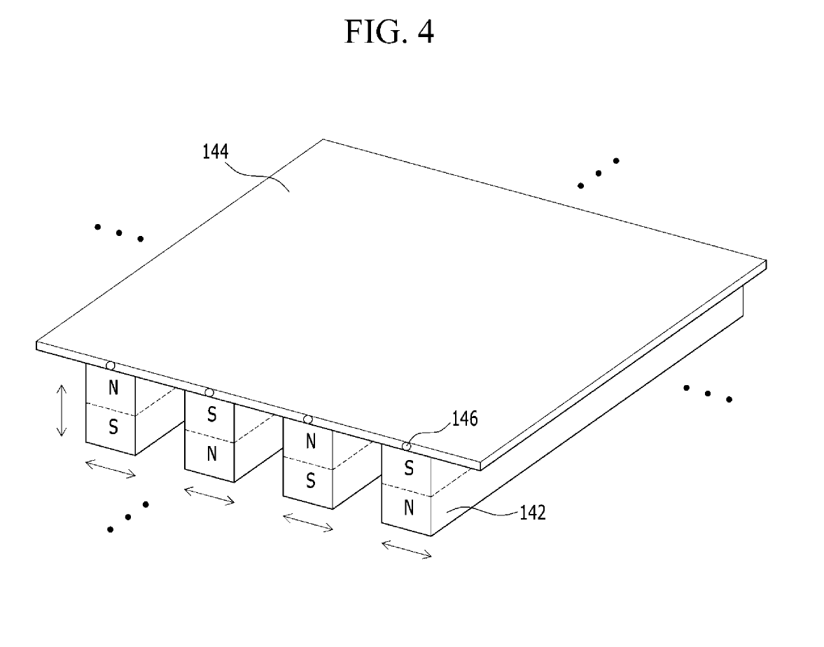

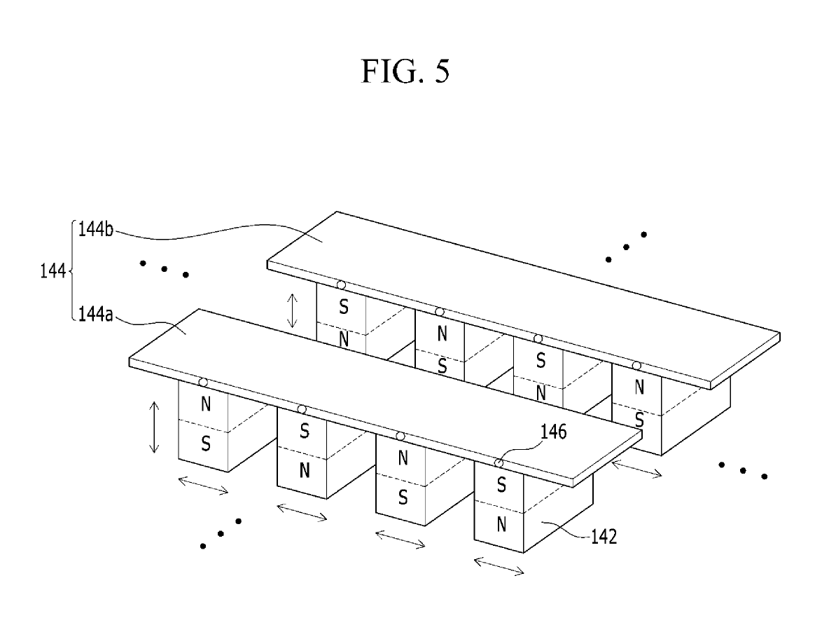

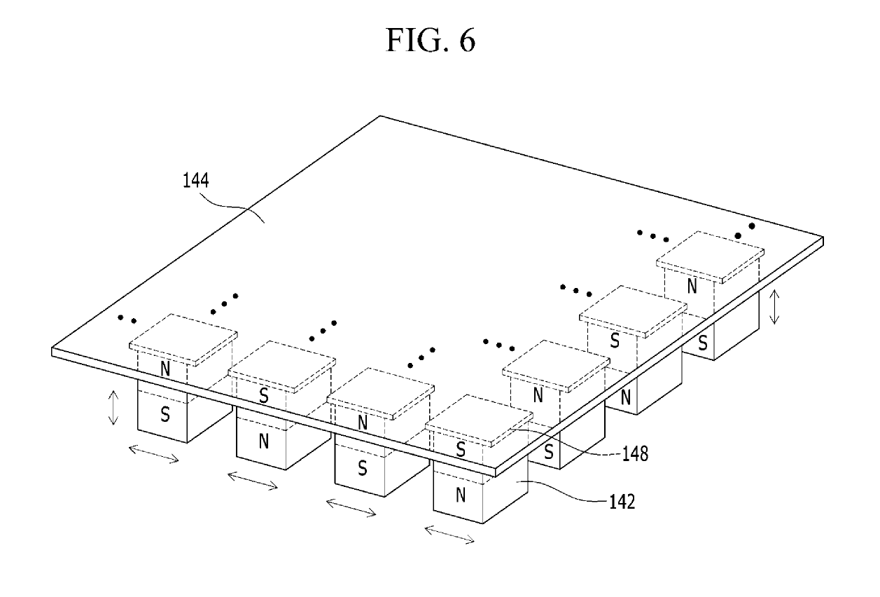

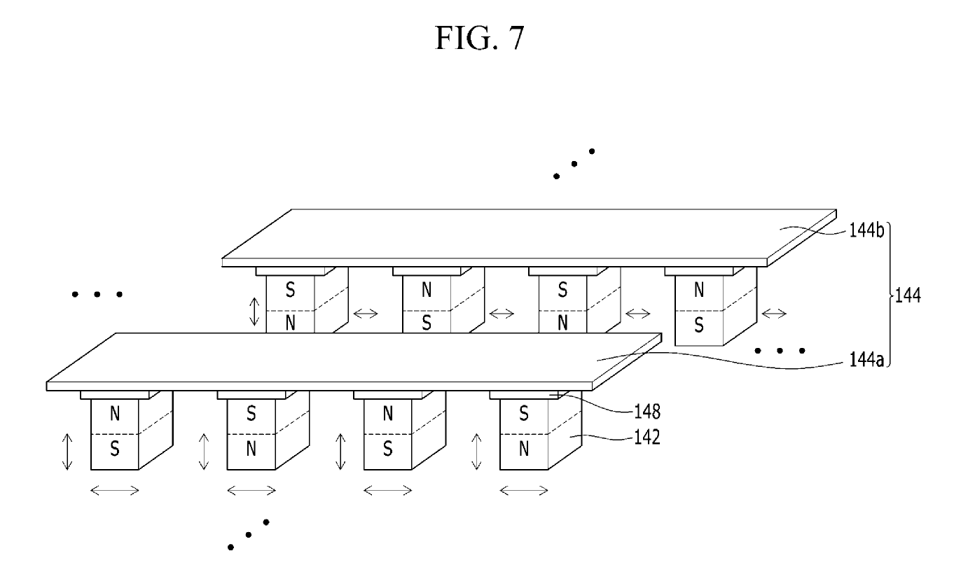

FIGS. 4 to 7 illustrate the plurality of magnets 142 which are coupled with one plate 144 or at least two plates 144a and 144b by the position adjustment gear 146 or the micro actuator 148, according to various embodiments of the present invention.

However, FIGS. 4 to 7 illustrates only some embodiments, and therefore any embodiment in which a plurality of magnets are movably coupled with the plate may be included in the scope of the present invention regardless of the number of plates or the magnet disposition.

Meanwhile, the plurality of magnets 142 according to the embodiment of the present invention may move along a first direction parallel with the plate 144 and may also move along a second direction vertical to the plate 144.

Each magnet 142 may be fixed to a moving means which is disposed along the second direction so that the plurality of magnets 142 may move along the second direction vertical to the plate 144. For example, the moving means may have a configuration like a cylinder but is not limited thereto, and the magnet 142 may move along the second direction by the micro actuator 148 itself.

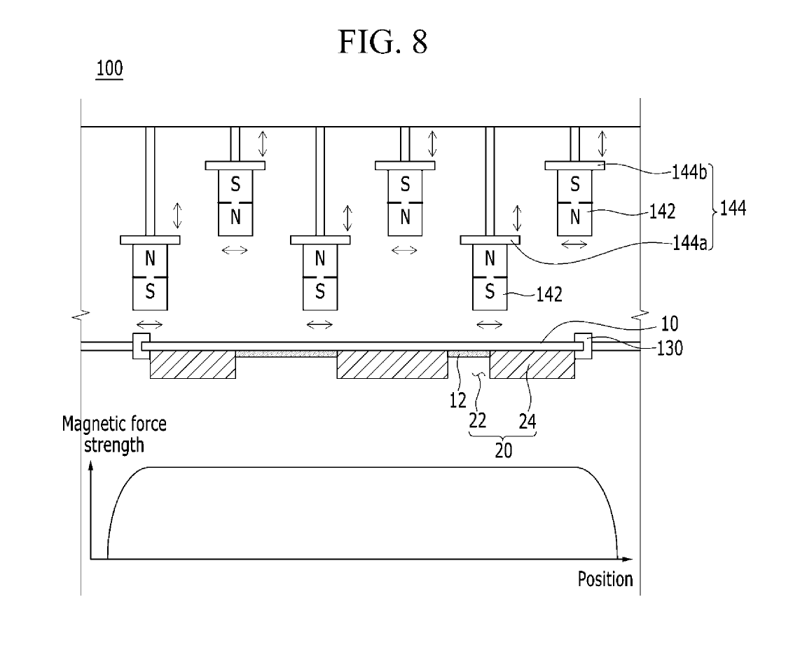

FIG. 8 illustrates a disposition of the plurality of magnets moving in the first direction and the second direction, according to an embodiment of the present invention and the magnetic force strength depending on the disposition. As illustrated in FIG. 8, when the magnet 142 is disposed by moving along the second direction, the magnetic force strength applied to the mask 20 may be uniform. Therefore, the mask 20 may be more firmly fixed while the deposition process is performed.

Each magnet 142 may individually move and the magnets 142 attached to the first plate 144a and the second plate 144b may move in groups according to the movement of each plate 144a and 144b.

In this case, according to the embodiment of the present invention, a disposition of the magnetic poles of the plurality of magnets 142 movably coupled with the plate 144 may each be opposite to a disposition of magnetic poles of adjacent magnets 142. According to the embodiment of the present invention, the case in which the magnetic poles of the plurality of magnets 142 are disposed to be opposite to each other may provide the stronger magnetic force strength than the case in which the magnetic poles of the plurality of magnets 142 are disposed in parallel with each other.

Hereinabove, the deposition apparatus 100 according to the embodiment of the present invention will be described. Any deposition apparatus 100 including the plurality of magnets 142 which may move to provide the higher magnetic force strength in the inactive region 24 of the mask 20 may be provided. Therefore, the mask 20 may be more firmly attached to the substrate 10 while the deposition apparatus 100 performs the deposition process, and therefore the defect occurrence rate of products may be reduced.

As described above, the present invention is described with reference to specific embodiments, but is not limited to the above-mentioned embodiments. Therefore, the present invention can be variously changed and modified from the description by a person skilled in the art to which the present invention pertains. Therefore, the modified examples or the changed examples are not to be individually construed from the technical spirit of the present invention and therefore the modified embodiments are construed to be included in claims of the present invention.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus comprising:
a chamber;
a deposition material supplier positioned in the chamber and configured to contain and supply a deposition material;
a substrate holder disposed in the chamber and configured to hold a substrate such that a major surface of the substrate faces the deposition material supplier; and
a mask retainer disposed in the chamber and configured to retain a mask disposed over the major surface of the substrate,
wherein the mask retainer comprises:
a base, and
a plurality of magnets coupled to the base, at least one of the plurality of magnets being movable with respect to the base, the plurality of magnets being configured to apply magnetic force to the mask such that the mask is fixed to the substrate without substantial movement of the mask with respect to the substrate during deposition of the deposition material.

2. The apparatus of claim 1, wherein the mask comprises an active region comprising a plurality of openings through which the deposition material passes and an inactive region which corresponds to a region other than the deposition region of the substrate, and wherein the plurality of magnets are disposed to overlap the inactive region.

3. The apparatus of claim 1, wherein the at least one of the plurality of magnets is configured to move relative to the substrate and the mask such that the plurality of magnets are disposed to overlap the inactive region when viewed in a direction perpendicular to the major surface.

4. The apparatus of claim 1, wherein the plurality of magnets are configured to move along a first direction parallel with the major surface of the substrate.

5. The apparatus of claim 3, wherein the plurality of magnets are configured to move along a second direction vertical to the major surface of the substrate.

6. The apparatus of claim 1, wherein each of the plurality of magnets is coupled with the base by a position adjustment gear.

7. The apparatus of claim 1, wherein each of the plurality of magnets is coupled with the base by a micro actuator.

8. The apparatus of claim 1, wherein the plurality of magnets comprise a first magnet and a second magnet immediately neighboring the first magnet, each of the first and second magnets having N and S magnetic poles, wherein the first and second magnets are arranged such that N magnetic pole of the first magnet and S pole of the second magnet are positioned adjacent the mask.

9. The apparatus of claim 1, wherein the deposition material supplier is configured to evaporate the deposition material such that the evaporated deposition material moves toward the substrate and is deposited over the major surface.

10. The apparatus of claim 1, wherein the substrate holder is configured to hold the substrate to be disposed between the mask and the plurality of magnets.

11. The apparatus of claim 1, wherein the plurality of magnets do not contact the mask.

12. The apparatus of claim 1, wherein the retainer does not contact the mask.

13. A method of making at least one organic light emitting display device, the method comprising:
providing the apparatus of claim 1;
placing a substrate comprising a major surface over which the deposition material is to be deposited such that the major surface faces the deposition material supplier;
placing a mask comprising an active region which comprises a plurality of openings through which a deposition material passes and an inactive region next to the active region, wherein the substrate is disposed between the mask and the plurality of magnets; and
supplying a deposition material contained in the deposition material supplier toward the substrate through the plurality of openings to deposit the deposition material over the major surface while the mask is fixed to the substrate without substantial movement of the mask with respect to the substrate by magnetic force applied to the mask by the plurality of magnets, thereby making an organic light emitting display device.

14. The method of claim 13, further comprising moving at least one of the plurality of magnets subsequently to placing the mask or prior to placing the mask such that the plurality of magnets overlap the inactive region when viewed in a direction perpendicular to the major surface while the mask is fixed to the substrate for deposition.

15. The method of claim 14, wherein none of the plurality of magnets overlaps the active region when viewed in the direction.

16. The method of claim 13, wherein supplying comprises evaporating the deposition material in the deposition material supplier, wherein the evaporated deposition material is transferred through the openings and deposited over the major surface.

17. The method of claim 13, wherein the mask comprises an additional active region comprising a plurality of openings through which the deposition material passes, wherein the inactive region is disposed between the active region and the additional active region.

18. The method of claim 17, wherein the deposition material is supplied through the openings of the additional active region, thereby forming an additional organic light emitting display device.

19. The method of claim 18, further comprising cutting the substrate to divide the organic light emitting display device and the additional organic light emitting display device.

20. The method of claim 13, wherein the deposition material comprises at least one selected from the group consisting of an organic light emitting material, a metal, a metal oxide electrode material, a semiconductor material and a color filter material.
